(19) United States
(12) Patent Application Publication
(10) Pub. No.: US 2025/0167086 A1
(43) Pub. Date: May 22, 2025

(54) SURFACE OXIDATION LAYER FOR METAL VOIDING REDUCTION

(71) Applicant: Taiwan Semiconductor Manufacturing Company, Ltd., Hsinchu (TW)

(72) Inventors: Man-Yun Wu, Hsinchu (TW); Hsiao-Kuan Wei, Taoyuan (TW); Jen-Po Lin, Hsinchu (TW); Ssu-Yu Ho, Hsinchu (TW)

(73) Assignee: Taiwan Semiconductor Manufacturing Company, Ltd., Hsinchu (TW)

(21) Appl. No.: 18/515,779

(22) Filed: Nov. 21, 2023

(51) Int. Cl. H01L 23/498; H01L 21/02; H01L 21/48

(52) U.S. Cl. CPC H01L 23/49822; H01L 21/02178; H01L 21/02244; H01L 21/02252; H01L 21/0228; H01L 21/0234; H01L 21/4857; H01L 23/49894

(57) ABSTRACT

A method includes: forming a redistribution layer (RDL) comprising metal material over a substrate; forming an oxidation layer of the metal material on sidewalls of the RDL; and depositing a passivation layer over the RDL and the oxidation layer, wherein the oxidation layer is formed between the RDL and the passivation layer; wherein the oxidation layer strengthens bonding between the RDL and the passivation layer to resist hydrogen induced voids from forming. The method may allow for performing a hydrogen plasma annealing treatment without hydrogen-induced voiding in top or bottom corners of the RDL. A device includes: an RDL comprising metal material formed over a substrate; a passivation layer formed over the RDL; and an oxidation layer of the metal material formed on sidewalls of the RDL between the RDL and the passivation layer. The device may be formed without voids in top or bottom corners of the RDL.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a section of an example semiconductor device at one stage in an integrated circuit manufacturing process, in accordance with an embodiment.

FIG. 2 is a cross-sectional view of a section of the example semiconductor device around the border between a redistribution layer (RDL) and a passivation laver at the same stage in an integrated circuit manufacturing process depicted in FIG. 1, in accordance with an embodiment.

FIG. 3 is a top view diagram illustrating an example RDL formed without an oxidation layer formed on sidewalls of the RDL.

FIG. 4 is a perspective view of an area of the RDL which illustrates a void formed in a top corner of the RDL.

FIG. 5 is a top view diagram illustrating an example RDL formed with an oxidation layer formed on sidewalls of the RDL, in accordance with some embodiments.

FIG. 6 is a process flow chart depicting an example method of semiconductor fabrication that includes forming an oxidation layer between an RDL and a passivation layer, in accordance with some embodiments.

FIGS. 7A-7F, are diagrams illustrating a semiconductor structure at various stages of fabrication, in accordance with some embodiments.

FIG. 8 is a diagram depicting an aluminum copper (AlCu) RDL with an aluminum oxide (AₗₓO_{y}) interface at the interface between the RDL and a passivation layer, in accordance with some embodiments.

FIG. 9 is diagram illustrating results from an example EDS line scan around the AlₓO_{y} interface, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Stress migration (SM) is a phenomenon that can occur in an integrated circuit (IC). SM can lead to voids and/or cracks forming within conductors that degrade the performance of an IC. For example, with SM, voids can form as result of vacancy migration and a hydrostatic stress gradient. Voids or cracks in a conductor can lead to open circuits or an increased resistance that impedes the performance of the IC.

When various materials with different thermal expansion coefficients are formed in an interconnect structure, SM can occur due to the formation of stress between different materials. Various thermal processes, such as high pressure annealing, during semiconductor processing can result in the formation of plastic deformation vacancies (e.g., small voids) or cracks in the interconnect structure. These small voids can be driven by stress migration due to the hydrostatic stress gradient to collect at high stress gradient areas in the interconnect structure to nucleate or form into a large void. Large voids can reduce or eliminate electrical contact between metal layers. Thus, SM may cause reduced electrical contact between conductive materials, which causes increased resistivity and can lead to device failure.

SM reliability issues can become more serious as geometries of semiconductor devices continue to shrink. SM effects may be minimized forming an oxidation layer at an interface between an RDL (e.g., AlCu RDL) and an overlying passivation layer. Forming an oxidation layer on sidewalls of the RDL may further improve film adhesion and provide pad well protection by preventing voids from forming due to SM. Presented herein are embodiments of semiconductor structures and of methods for forming semiconductor structures with an oxidation layer on sidewalls of RDL.

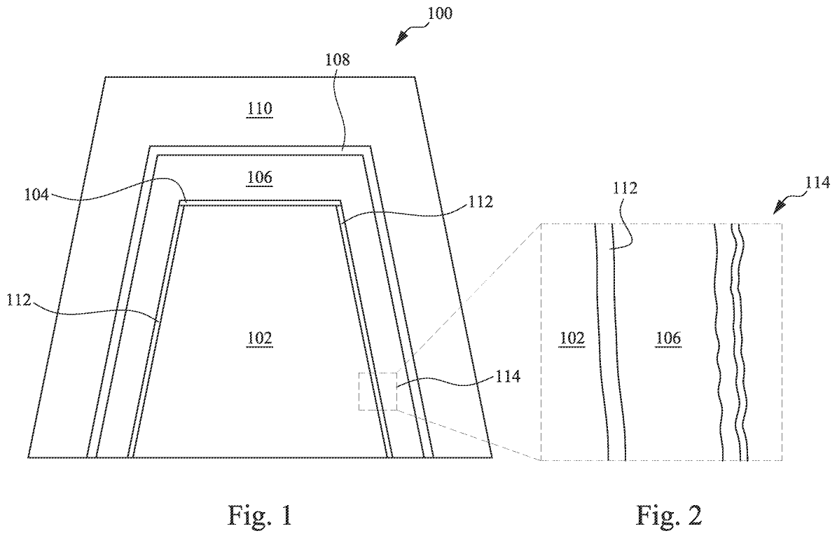

FIG. 1 is a cross-sectional view of a section of an example semiconductor device 100 at one stage in an integrated circuit manufacturing process in accordance with an embodiment. Shown are sections of a redistribution layer (RDL) 102 that includes a metal material and is formed above a substrate (not shown), a pattern film 104 above a top surface of the RDL 102, a passivation layer 106 over the pattern film 104 and the top surface of the RDL 102, an etch stop layer (ESL) 108 over the passivation layer 106, and a gap fill layer 110 over the ESL 108. The example semiconductor section also includes an oxidation layer 112 of the metal material formed on sidewalls of the RDL 102 between the RDL 102 and the passivation layer 106. The oxidation layer 112 can strengthen bonding between the RDL 102 and the passivation layer 106 to resist hydrogen induced voids from forming in the RDL 102.

FIG. 2 is a cross-sectional view of a section 114 of the example semiconductor device 100 around the border between the RDL 102 and the passivation laver 106 at the same stage in an integrated circuit manufacturing process depicted in FIG. 1, in accordance with an embodiment. Illustrated are the RDL 102 comprising a metal material formed over a substrate, the passivation layer 106 formed over the RDL, and the oxidation layer 112 of the metal material formed on sidewalls of the RDL 102 between the RDL 102 and the passivation layer 106.

The semiconductor substrate (not shown) may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used. Although not shown, it will be recognized that the substrate may further comprise a plurality of isolation features, such as shallow trench isolation (STI) features or local oxidation of silicon (LOCOS) features. The isolation features may isolate various microelectronic elements formed in and/or upon the substrate. Examples of the types of microelectronic elements that may be formed in the substrate include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other suitable elements. Various processes are performed to form the various microelectronic elements, including but not limited to one or more of deposition, etching, implantation, photolithography, annealing, and other suitable processes. The microelectronic elements are interconnected to form the integrated circuit device, which may comprise one or more of a logic device, memory device (e.g., SRAM), radio frequency (RF) device, input/output (I/O) device, system-on-chip (SoC) device, and other suitable types of devices.

The RDL 102 is formed above an interconnect structure on the substrate to reroute an electrical connection at a top metal pad of the interconnect structure to a desired location such as an under-bump metallization (UBM) structure, a solder bump, and/or a copper pillar bump, for facilitating external electrical connections. The ability to redistribute points can enable higher contact density. A portion of the RDL 102 is coupled to a top metal pad of an interconnect structure on the substrate. In various embodiments the RDL 102 is formed from Aluminum and/or aluminum copper (AlCu) and may include multiple layers.

The pattern film 104 is patterned and used as a mask for patterning the RDL 102. In various embodiments, the pattern film 104 is formed from an oxynitride material.

After patterning the RDL 102, an oxidation layer 112 is formed on sidewalls of the RDL 102. In various embodiments, the oxidation layer includes aluminum oxide (AlₓO_{y}, where x>0 and y>0). In various embodiments, the AlₓO_{y} is formed by a plasma oxidation process in a plasma chamber. In the plasma chamber, the surface of the Al metal of the RDL pad can be oxidized by a plasma containing N₂O or O₂, such as an oxygen (O₂) plasma, a Nitrous oxide (N₂O) plasma, or a nitrogen oxide (NO) plasma. This can result in the formation of Al_{y}Oₓ. In other embodiments, the AlₓO_{y} may be formed by a deposition process. For example, an Al_{y}Oₓ film can be deposited by an ALD or CVD process with an Al precursor and oxidant.

The passivation layer 106 may be formed in the same chamber as the AlₓO_{y}. The passivation layer may be grown and of a non-organic material, such as un-doped silicate glass (USG), silicon oxide (SiO₂), or other material. The passivation layer 106 may be formed by any suitable method, such as chemical vapor deposition (CVD), physical vapor deposition (PVD), or others.

The etch stop layer (ESL) 108 may be formed by deposition such as CVD. In various embodiments, the ESL is formed from silicon oxynitride (SiON).

The gap fill layer 110 may include inorganic material (e.g., silicon dioxide (SiO₂), SiON, silicon carbonitride (SiCN), silicon carbon oxide (SiCO), or the like), organic material (e.g., epoxy, polyimide (PI), polybenzoxazole (PBO), or the like), or the mixture of inorganic and organic materials (e.g., the mixture of silicon dioxide and epoxy, or the like). The gap fill layer 110 may be formed through chemical vapor deposition (CVD), high-density plasma chemical vapor deposition (HDPCVD), plasma-enhanced chemical vapor deposition (PECVD), atomic layer deposition (ALD), or other suitable techniques.

Further fabrication operations may include a nitride layer being formed over the gap fill layer 110 and a hydrogen plasma annealing treatment performed. Without the oxidation layer, voids may form in top and bottom corners of the RDL 302.

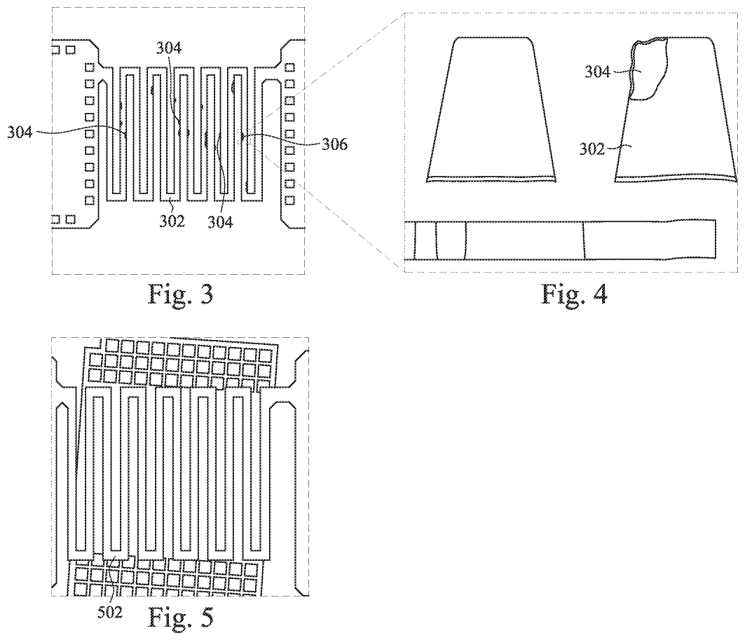

FIG. 3 is a top view diagram illustrating an example RDL 302 formed without an oxidation layer formed on sidewalls of the RDL. The example RDL 302 includes a plurality of voids 304 that formed after a hydrogen plasma annealing treatment was performed. FIG. 4 is a perspective view of an area 306 of the RDL 302 which illustrates one of the voids 304 formed in a top corner of the RDL 302. FIG. 5 is a top view diagram illustrating an example RDL 502 formed with an oxidation layer formed on sidewalls of the RDL 502. In this example, the RDL 502 did not exhibit voids in the RDL 502 after a hydrogen plasma annealing treatment was performed.

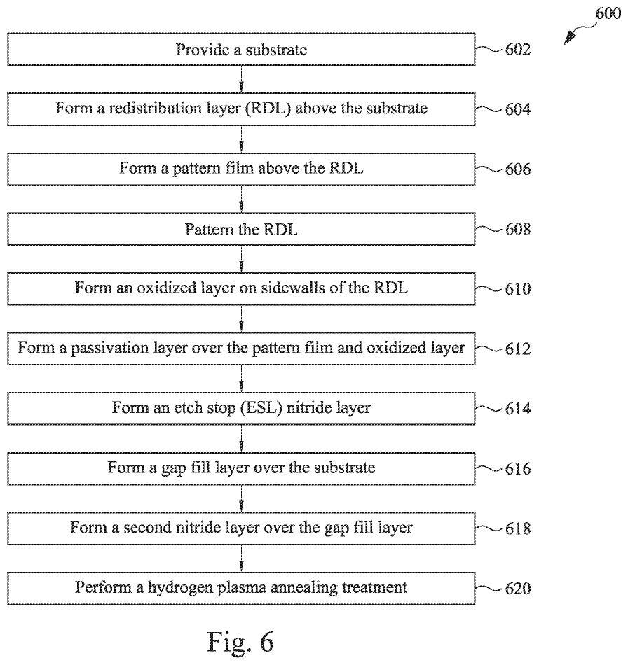

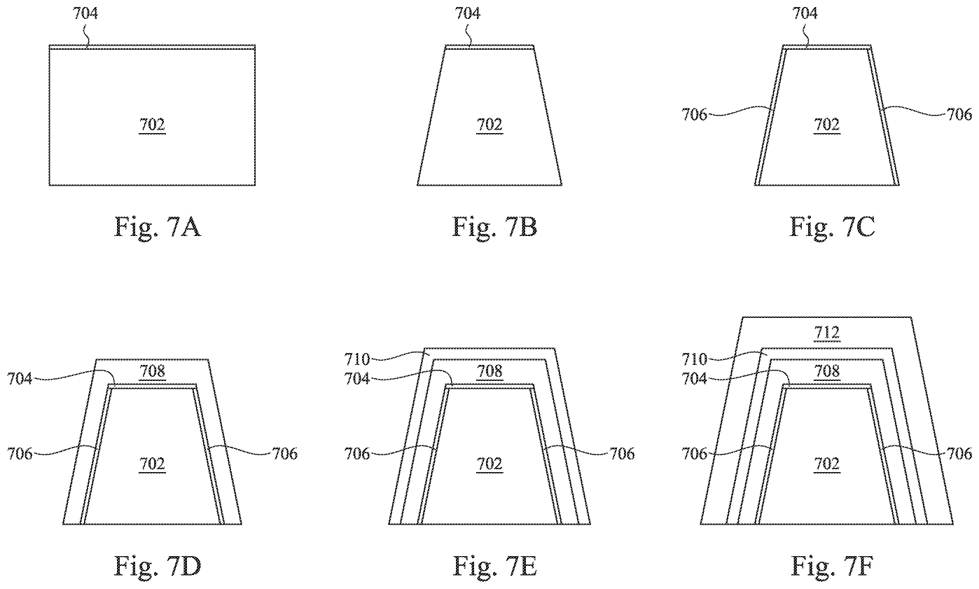

FIG. 6 is a process flow chart depicting an example method 600 of semiconductor fabrication that includes forming an oxidation layer between an RDL and a passivation layer to strengthen bonding between the RDL and the passivation layer to resist hydrogen induced voids from forming. FIG. 6 is described in conjunction with FIGS. 7A-7F, which illustrate a semiconductor structure at various stages of fabrication in accordance with some embodiments. The method 600 is merely an example and is not intended to limit the present disclosure beyond what is explicitly recited in the claims. Additional steps may be provided before, during, and after method 600, and some of the steps described can be moved, replaced, or eliminated for additional embodiments of method 600. Additional features may be added in the semiconductor structure depicted in the figures, and some of the features described below can be replaced, modified, or eliminated in other embodiments.

As with the other method embodiments and exemplary devices discussed herein, it is understood that parts of the semiconductor structures may be fabricated by typical semiconductor technology process flow, and thus some processes are only briefly described herein. Further, the exemplary semiconductor structures may include various other devices and features, such as other types of devices such as additional transistors, bipolar junction transistors, resistors, capacitors, inductors, dials, fuses, and/or other logic devices, etc., but is simplified for better understanding of concepts of the present disclosure.

At block 602, the example method 600 includes providing a substrate. In various embodiments, the substrate includes an interconnect structure in a dielectric layer over the substrate.

At block 604, the example method 600 includes forming a redistribution layer (RDL) above an interconnect structure on the substrate. In various embodiments, the RDL is coupled to a top metal pad of the interconnect structure on the substrate to reroute an electrical connection at the top metal pad to a desired location. In various embodiments the RDL 102 is formed from Aluminum (Al), aluminum copper (AlCu), Cu, or some other metal.

At block 606, the example method 600 includes forming a pattern film above the RDL. In various embodiments, the pattern film 104 is formed from an oxynitride material. Referring to the example of FIG. 7A, in an embodiment of blocks 604 and 606, depicted is a pattern film 704 formed over the RDL 702.

At block 608, the example method 600 includes patterning the RDL. Patterning the RDL includes patterning the pattern film and etching the RDL using the pattern film as an etching mask. The RDL may be etched using anisotropic etching operations. Referring to the example of FIG. 7B, in an embodiment of block 608, the pattern film 704 and the RDL 702 have been patterned.

At block 610, the example method 600 includes forming an oxidation layer on sidewalls of the RDL. In various embodiments, the oxidation layer includes an oxidation layer of the metal material of the RDL. In various embodiments, the oxidation layer includes aluminum oxide (AlₓO_{y}). In various embodiments, the AlₓO_{y} is formed with a thickness of between about 20 A to about 100 A. In various embodiments, this thickness level is sufficient to resist the formation of voids in the RDL due to SM. In various embodiments, the AlₓO_{y} is formed by a plasma oxidation process in a plasma chamber. In other embodiments, the AlₓO_{y} is formed by a deposition process. In various embodiments, the plasma oxidation process includes an oxygen (O2) plasma, a Nitrous oxide (N2O) plasma, or a nitrogen oxide (NO) plasma and/or their mixture. Referring to the example of FIG. 7C, in an embodiment of block 610 an oxidation layer 706 has been formed on sidewalls of the RDL 702.

At block 612, the example method 600 includes forming a passivation layer over the pattern film and oxidation layer. The passivation layer may be grown and of a non-organic material, such as un-doped silicate glass (USG), silicon oxide (SiO₂), or other material.

Referring to the example of FIG. 7D, in an embodiment of block 612 a passivation layer 708 has been formed over the pattern film 704 and oxidation layer 706. The passivation layer 708 may be formed by CVD, high-density plasma CVD (HDPCVD), plasma-enhanced CVD (PECVD), sub-atmospheric CVD (SACVD), other suitable methods, or combinations thereof.

In the present embodiments, the RDL 702 has an oxidation layer 706 on sidewalls of the RDL 702 at its interface with the passivation layer 708, thereby alleviating stress concentrations between the RDL 702 and the passivation layer 708 arising from any potential mismatched thermal expansion therebetween. Without forming an oxidation layer on sidewalls of the RDL, any stress experienced by the passivation layer may concentrate at corners of the RDL between the RDL and the passivation layer resulting in structural defects including cracks, delamination, and/or other defects. In some instances, such stress may arise from uneven thermal expansion between the passivation layer and a subsequently-formed protection layer. To address these challenges, the present disclosure provides methods of forming an oxidation layer on sidewalls of the RDL. By forming an oxidation layer on sidewalls of the RDL, improved interfacial adhesion between the RDL and the passivation layer can be achieved to prevent cracks, delamination, and/or other defects. By forming an oxidation layer on sidewalls of the RDL, AlCu voiding can be reduced for better thermal cycling reliability. By forming an oxidation layer on sidewalls of the RDL, an AlCu/AlₓO_{y} interface can be provided to prevent hydrogen-induced voiding.

At block 614, the example method 600 includes forming an ESL layer over the passivation layer. The ESL may be formed by deposition such as CVD. In various embodiments, the ESL is formed from silicon oxynitride (SiON). Referring to the example of FIG. 7D, in an embodiment of block 614, an ESL layer 710 has been formed over the passivation layer 708.

At block 616, the example method 600 includes forming a gap fill layer over the ESL layer. The gap fill layer may be formed by suitable deposition techniques. In some embodiments, the material of the gap fill layer includes silicon oxide (SiOx, where x>0), silicon oxynitride (SiOxNy, where x>0 and y>0), silicon nitride (SiNx, where x>0), or other suitable dielectric material. In some alternative embodiments, the encapsulating material of the gap fill layer is formed through a film deposition process. For example, the film deposition process may include CVD, HDPCVD, PECVD, atomic layer deposition (ALD), or combinations thereof. Referring to the example of FIG. 7E, in an embodiment of block 616, a gap fill layer 712 is formed over the ESL layer 710.

At block 618, the example method 600 includes forming a nitride layer over the gap fill layer. At block 620 the example method 600 includes performing a hydrogen plasma annealing treatment.

Because the RDL 702 has an oxidation layer 706 on sidewalls of the RDL 702 at its interface with the passivation layer 708, stress concentrations between the RDL 702 and the passivation layer 708 arising from any potential mismatched thermal expansion therebetween has been alleviated. By forming an oxidation layer on sidewalls of the RDL, improved interfacial adhesion between the RDL and the passivation layer can be achieved to prevent cracks, delamination, and/or other defects. By forming an oxidation layer on sidewalls of the RDL, AlCu voiding can be reduced for better thermal cycling reliability. By forming an oxidation layer on sidewalls of the RDL, an AlCu/AlₓO_{y} interface can be provided to prevent hydrogen-induced voiding.

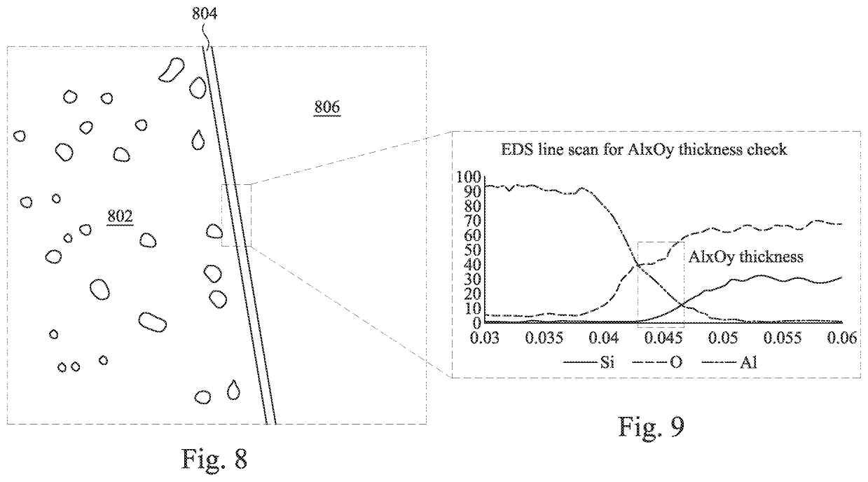

Transmission electron microscopy (TEM), energy dispersive X-Ray (EDX/EDS) mapping, and line scan can be used to show evidence of successful plasma oxidation on AlCu. FIG. 8 is a diagram depicting an AlCu RDL 802 with an AlₓO_{y} interface 804 at the interface between the RDL 802 and a passivation layer 806 above the RDL 802. FIG. 9 is diagram illustrating results from an example EDS line scan 902 around the AlₓO_{y} interface 804. The example EDS line scan 902 illustrates the concentration of Si, Al, and O around the AlₓO_{y} interface 804. In particular, the example EDS line scan 902 illustrates that at the AlₓO_{y} interface 804 the concentration of aluminum (Al) decreases from about 40% to about 15%, the concentration of oxygen (O) increase from about 40% to about 55%, and the concentration of silicon (Si) increases from about 0% to about 10%. This illustrates the penetration of oxygen into the Al from the bottom interface of the passivation layer.

Herein, embodiments provide improved resistance to problems associated with stress migration (SM). The techniques described herein may be useful for multiple chip stacking in 3DIC(/SoIC) packages, face-to-face MCM, CoWoS and InFO packages, among other packaging techniques. Embodiments of the present disclosure offer advantages over the existing art, though it is understood that other embodiments may offer different advantages, not all advantages are necessarily discussed herein, and no particular advantage is required for all embodiments.

In some aspects, the techniques described herein relate to a device including: a redistribution layer (RDL) including a metal material formed over a substrate; a passivation layer formed over the RDL; and an oxidation layer of the metal material formed on sidewalls of the RDL between the RDL and the passivation layer.

In some aspects, the techniques described herein relate to a device, wherein the metal material includes Aluminum (Al) and the oxidation layer includes Aluminum oxide.

In some aspects, the techniques described herein relate to a device, wherein the passivation layer includes Silicon oxide (SiO₂).

In some aspects, the techniques described herein relate to a device, wherein the RDL is without voids formed in top or bottom corners of the RDL.

In some aspects, the techniques described herein relate to a device, wherein the oxidation layer of the metal material was formed in a plasma chamber using one or more of an oxygen (O₂) plasma, Nitrous oxide (N₂O) plasma, or nitrogen oxide (NO) plasma.

In some aspects, the techniques described herein relate to a device, wherein the oxidation layer of the metal material was formed from an aluminum oxide film that was deposited by an atomic layer deposition (ALD) or chemical vapor deposition (CVD) process with an Al precursor and oxidant.

In some aspects, the techniques described herein relate to a device, wherein the metal material includes Copper (Cu) and the oxidation layer includes Cu oxide.

In some aspects, the techniques described herein relate to a device, wherein the oxidation layer has a thickness between approximately 20 angstroms to approximately 100 angstroms.

In some aspects, the techniques described herein relate to a method including: forming a redistribution layer (RDL) including a metal material over a substrate; forming an oxidation layer of the metal material on sidewalls of the RDL; and depositing a passivation layer over the RDL and the oxidation layer, wherein the oxidation layer is formed between the RDL and the passivation layer.

In some aspects, the techniques described herein relate to a method, wherein forming the oxidation layer includes performing a plasma oxidation process to form the oxidation layer on sidewalls of the RDL.

In some aspects, the techniques described herein relate to a method, wherein performing the plasma oxidation process includes forming the oxidation layer using plasma including one or more of an oxygen (O₂) plasma, a Nitrous oxide (N₂O) plasma, and a nitrogen oxide (NO) plasma.

In some aspects, the techniques described herein relate to a method, wherein forming the oxidation layer includes depositing an aluminum oxide film by an atomic layer deposition (ALD) or chemical vapor deposition (CVD) process with an Al precursor and oxidant.

In some aspects, the techniques described herein relate to a method, wherein forming the oxidation layer includes forming the oxidation layer with a thickness between approximately 20 angstroms to approximately 100 angstroms.

In some aspects, the techniques described herein relate to a method, wherein the metal material includes Aluminum (Al) and the oxidation layer includes Aluminum oxide.

In some aspects, the techniques described herein relate to a method, wherein depositing the passivation layer includes depositing the passivation layer in a plasma chamber after performing the plasma oxidation process in the plasma chamber.

In some aspects, the techniques described herein relate to a method including: forming a redistribution layer (RDL) including Aluminum copper (AlCu) over a substrate; oxidizing sidewalls of the RDL to form an Aluminum oxidation layer on the sidewalls of the RDL; depositing a passivation layer over the RDL and the Aluminum oxidation layer, wherein the Aluminum oxidation layer is formed between the RDL and the passivation layer; and performing a hydrogen plasma annealing treatment without hydrogen-induced voiding in top or bottom corners of the RDL.

In some aspects, the techniques described herein relate to a method, wherein oxidizing sidewalls of the RDL to form the Aluminum oxidation layer includes performing a plasma oxidation process to form the Aluminum oxidation layer on sidewalls of the RDL.

In some aspects, the techniques described herein relate to a method, wherein performing the plasma oxidation process includes oxidizing sidewalls of the RDL to form the Aluminum oxidation layer using plasma including one or more of an oxygen (O₂) plasma, a nitrous oxide (N₂O) plasma, and a nitrogen oxide (NO) plasma.

In some aspects, the techniques described herein relate to a method, wherein depositing the passivation layer includes forming the passivation layer in a plasma chamber after performing the plasma oxidation process in the plasma chamber.

In some aspects, the techniques described herein relate to a method, wherein oxidizing sidewalls of the RDL to form the Aluminum oxidation layer includes forming the Aluminum oxidation layer to a thickness between approximately 20 angstroms to approximately 100 angstroms.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A device comprising:
a redistribution layer (RDL) comprising a metal material formed over a substrate;
a passivation layer formed over the RDL; and
an oxidation layer of the metal material formed on sidewalls of the RDL between the RDL and the passivation layer.

2. The device of claim 1, wherein the metal material comprises Aluminum (Al) and the oxidation layer comprises Aluminum oxide.

3. The device of claim 2, wherein the passivation layer comprises Silicon oxide (SiO₂).

4. The device of claim 3, wherein the RDL is without voids formed in top or bottom corners of the RDL.

5. The device of claim 2, wherein the oxidation layer of the metal material was formed in a plasma chamber using one or more of an oxygen (O₂) plasma, Nitrous oxide (N₂O) plasma, or nitrogen oxide (NO) plasma.

6. The device of claim 2, wherein the oxidation layer of the metal material was formed from an aluminum oxide film that was deposited by an atomic layer deposition (ALD) or chemical vapor deposition (CVD) process with an Al precursor and oxidant.

7. The device of claim 1, wherein the metal material comprises Copper (Cu) and the oxidation layer comprises Cu oxide.

8. The device of claim 1, wherein the oxidation layer has a thickness between approximately 20 angstroms to approximately 100 angstroms.

9. A method comprising:
forming a redistribution layer (RDL) comprising a metal material over a substrate;
forming an oxidation layer of the metal material on sidewalls of the RDL; and
depositing a passivation layer over the RDL and the oxidation layer, wherein the oxidation layer is formed between the RDL and the passivation layer.

10. The method of claim 9, wherein forming the oxidation layer comprises performing a plasma oxidation process to form the oxidation layer on sidewalls of the RDL.

11. The method of claim 10, wherein performing the plasma oxidation process comprises forming the oxidation layer using plasma comprising one or more of an oxygen (O₂) plasma, a Nitrous oxide (N₂O) plasma, and a nitrogen oxide (NO) plasma.

12. The method of claim 9, wherein forming the oxidation layer comprises depositing an aluminum oxide film by an atomic layer deposition (ALD) or chemical vapor deposition (CVD) process with an Al precursor and oxidant.

13. The method of claim 9, wherein forming the oxidation layer comprises forming the oxidation layer with a thickness between approximately 20 angstroms to approximately 100 angstroms.

14. The method of claim 9, wherein the metal material comprises Aluminum (Al) and the oxidation layer comprises Aluminum oxide.

15. The method of claim 11, wherein depositing the passivation layer comprises depositing the passivation layer in a plasma chamber after performing the plasma oxidation process in the plasma chamber.

16. A method comprising:
forming a redistribution layer (RDL) comprising Aluminum copper (AlCu) over a substrate;
oxidizing sidewalls of the RDL to form an Aluminum oxidation layer on the sidewalls of the RDL;
depositing a passivation layer over the RDL and the Aluminum oxidation layer, wherein the Aluminum oxidation layer is formed between the RDL and the passivation layer; and
performing a hydrogen plasma annealing treatment without hydrogen-induced voiding in top or bottom corners of the RDL.

17. The method of claim 16, wherein oxidizing sidewalls of the RDL to form the Aluminum oxidation layer comprises performing a plasma oxidation process to form the Aluminum oxidation layer on sidewalls of the RDL.

18. The method of claim 17, wherein performing the plasma oxidation process comprises oxidizing sidewalls of the RDL to form the Aluminum oxidation layer using plasma comprising one or more of an oxygen (O₂) plasma, a nitrous oxide (N₂O) plasma, and a nitrogen oxide (NO) plasma.

19. The method of claim 18, wherein depositing the passivation layer comprises forming the passivation layer in a plasma chamber after performing the plasma oxidation process in the plasma chamber.

20. The method of claim 16, wherein oxidizing sidewalls of the RDL to form the Aluminum oxidation layer comprises forming the Aluminum oxidation layer to a thickness between approximately 20 angstroms to approximately 100 angstroms.
